(19) United States
(12) Patent Application Publication
(10) Pub. No.: US 2009/0117700 A1
(43) Pub. Date: May 7, 2009

(54) Method for Manufacturing a Trench Power Transistor

(76) Inventors: Wei-Chieh Lin, Hsinchu City (TW); Jen-Hao Yeh, Kaohsiung County (TW); Ming-Jang Lin, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/135,217

(22) Filed: Jun. 9, 2008

Related U.S. Application Data
(60) Provisional application No. 60/985,289, filed on Nov. 5, 2007.

(51) Int. Cl. H01L 21/336

(52) U.S. Cl. 438/270; 257/E21.428

(57) ABSTRACT

A method for manufacturing a trench power transistor includes providing a substrate, forming an epitaxy layer on the substrate, performing a dry etching process on the epitaxy layer for generating a first trench, forming a gate oxide layer in the first trench and depositing poly-Si on the gate oxide layer in the first trench, performing a boron implant process on regions outside the first trench and inside the epitaxy layer, performing an arsenic implant process on regions beside the first trench and inside the epitaxy layer, depositing a first dielectric material on the surface of the epitaxy layer, performing a dry etching process on the epitaxy layer for generating a second trench, depositing a conductive material in the second trench for forming a p-well junction on sidewalls of the second trench, and performing a wet immersion process for forming a contact hole, and depositing frontside and backside metal.

### CROSS REFERENCE TO RELATED APPLICATIONS

This application claims the benefit of U.S. Provisional Application No. 60/985,289, filed on Nov. 5, 2007 and entitled “Novel Junction Pinch Power Device”, the contents of which are incorporated herein by reference.

### BACKGROUND OF THE INVENTION

1. Field of the Invention

The present invention relates to a method for manufacturing a trench power transistor, and more particularly, to method for manufacturing a trench power transistor capable of decreasing capacitance between gate and drain.

2. Description of the Prior Art

A trench power transistor is a typical semiconductor device in power management application, such as switching power supply, power control IC of a computer system or peripherals, power supply of a backlight, motor controller, etc. The major criteria for selecting power devices are power loss and power dissipation. In practice, resistance loss and switching loss between transient current and voltage waveforms dominate power loss of a power device. Therefore, to solve the above-mentioned problem, capacitance and charges of the trench power transistor need to be decreased. Besides, in the trench power transistor, the capacitance and charges are positively related. That is, the greater the capacitance is, the greater the charges are. The switching speed of gate is affected by the charges, which becomes slower as the chargers become greater, and faster as the chargers become smaller. Certainly, the fast switching speed is expected.

In order to gain the faster switching speed, the prior art provides modifications on the structure of the trench power transistor to reduce capacitance and charges. For example, U.S. Pat. No. 6,084,264 discloses a trench MOSFET having a thicker bottom oxide for decreasing gate capacitance. U.S. Pat. No. 6,291,298 discloses a trench semiconductor device decreasing gate capacitance via combinations of materials with different dielectric constants. Furthermore, structures as disclosed in U.S. Pat. No. 6,979,621 and No. 5,801,417 deepen trenches by floating gate, so as to decrease capacitance.

In order to improve U.S. Pat. No. 6,084,264, 6,291,298, 6,979,621, and 5,801,417, the applicant applies another application, a power transistor capable of decreasing capacitance between gate and drain, as shown in FIG. 1. In FIG. 1, a trench power transistor 10 comprises a backside mental layer 101, a substrate 102, a semiconductor layer 104, and a frontside mental layer 106. The semiconductor layer 104 comprises a first trench structure 201, a second trench structure 202, a p-body region 204, n+ source region 206, and a dielectric layer 209. The first trench structure 201 comprises a gate oxide layer 210 formed around a trench 211 with poly-Si deposited. The second trench structure 202 comprises a p-well junction 212 formed around a trench 213 with a conductive material implanted.

In the trench power transistor 10, the second trench structures 202 beside the first trench structure 201 pinch the junctions to deepen the depletion region, so that the capacitance between gate and drain can be decreased. However, how to manufacture the trench power transistor 10 is not disclosed.

### SUMMARY OF THE INVENTION

It is therefore a primary objective of the claimed invention to provide a power transistor capable of decreasing capacitance between gate and drain.

The present invention discloses a method for manufacturing a trench power transistor, which comprises providing a substrate, forming an epitaxy layer on the substrate, performing a dry etching process on the epitaxy layer for generating a first trench, forming a gate oxide layer in the first trench and depositing poly-Si on the gate oxide layer in the first trench, performing a boron implant process on regions outside the first trench and inside the epitaxy layer, performing an arsenic implant process on regions beside the first trench and inside the epitaxy layer, depositing a first dielectric material on the surface of the epitaxy layer, performing a dry etching process on the epitaxy layer for generating a second trench, depositing a conductive material in the second trench for forming a p-well junction on sidewalls of the second trench, and performing a wet immersion process for forming a contact hole, and depositing a frontside metal and a backside metal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a cross-sectional diagram of a trench power transistor.

FIG. 2 illustrates a schematic diagram of a semiconductor manufacturing process according to an embodiment of the present invention.

FIG. 3 to FIG. 9 illustrate cross-sectional diagrams of manufacturing a trench power transistor according to the semiconductor manufacturing process shown in FIG. 2.

### DETAILED DESCRIPTION

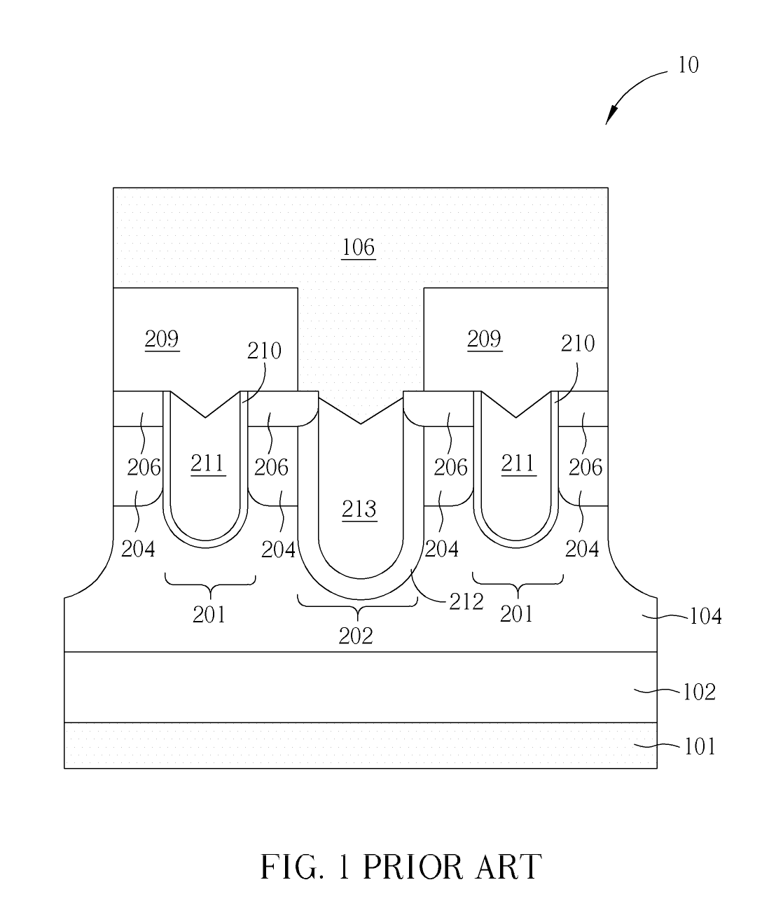

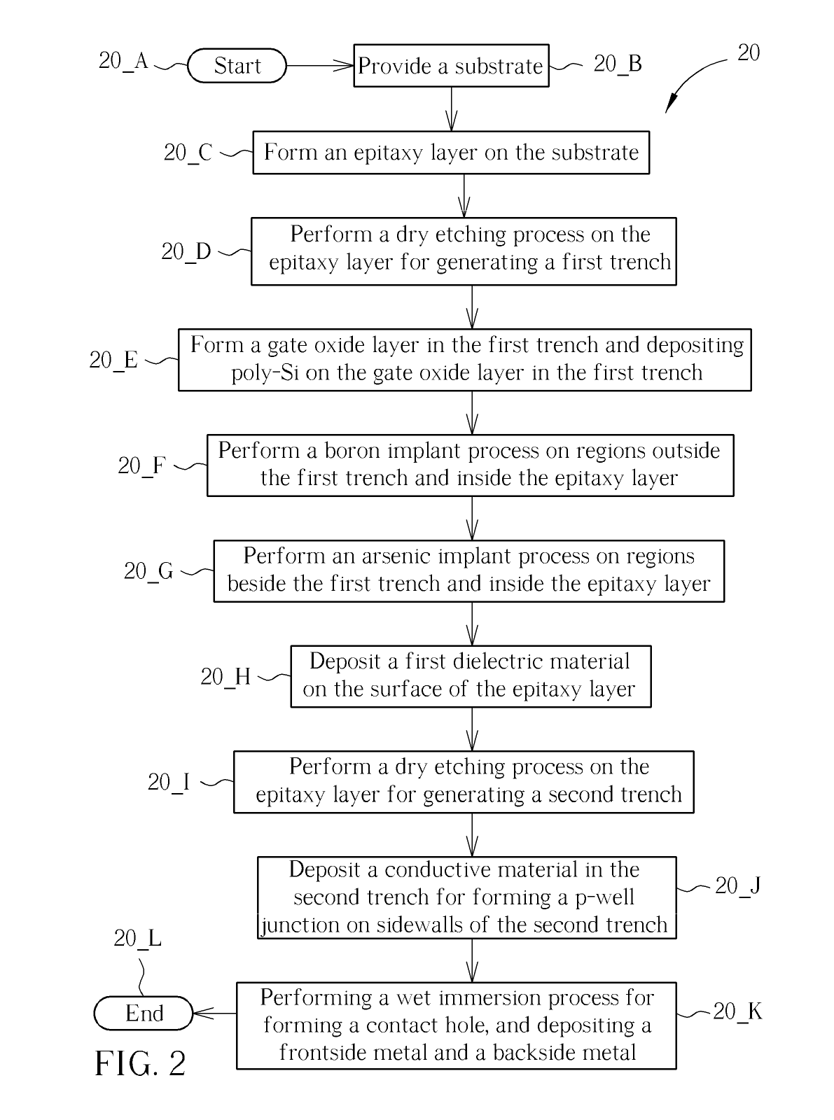

Please refer to FIG. 2, which illustrates a schematic diagram of a semiconductor manufacturing process 20 according to an embodiment of the present invention. The semiconductor manufacturing process 20 is utilized for manufacturing the trench power transistor 10 as shown in FIG. 1, and comprises the following steps:

Step 20_A: Start.

Step 20_B: Provide a substrate.

Step 20_C: Form an epitaxy layer on the substrate.

Step 20_D: Perform a dry etching process on the epitaxy layer for generating a first trench.

Step 20_E: Form a gate oxide layer in the first trench and depositing poly-Si on the gate oxide layer in the first trench.

Step 20_F: Perform a boron implant process on regions outside the first trench and inside the epitaxy layer.

Step 20_G: Perform an arsenic implant process on regions beside the first trench and inside the epitaxy layer.

Step 20_H: Deposit a first dielectric material on the surface of the epitaxy layer.

Step 20_I: Perform a dry etching process on the epitaxy layer for generating a second trench.

Step 20_J: Deposit a conductive material in the second trench for forming a p-well junction on sidewalls of the second trench.

Step 20_K: Performing a wet immersion process for forming a contact hole, and depositing a frontside metal and a backside metal.

Step 20_L: End.

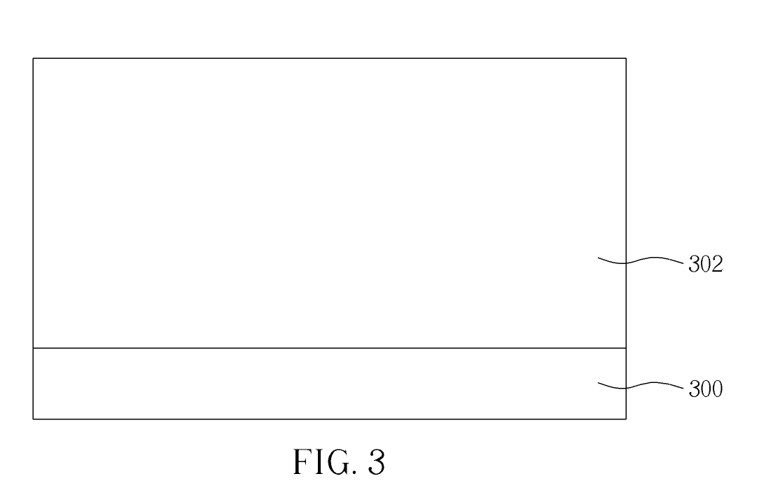

To clearly specify the semiconductor manufacturing process 20, please refer to FIG. 3 to FIG. 9. FIG. 3 to FIG. 9 illustrate cross-sectional diagrams of manufacturing a trench power transistor according to the semiconductor manufacturing process 20. In FIG. 3, the semiconductor manufacturing process 20 provides a substrate 300, which is preferably an n+ substrate, and forms an epitaxy layer 302, which is preferably an n− epitaxy layer, on the substrate 300.

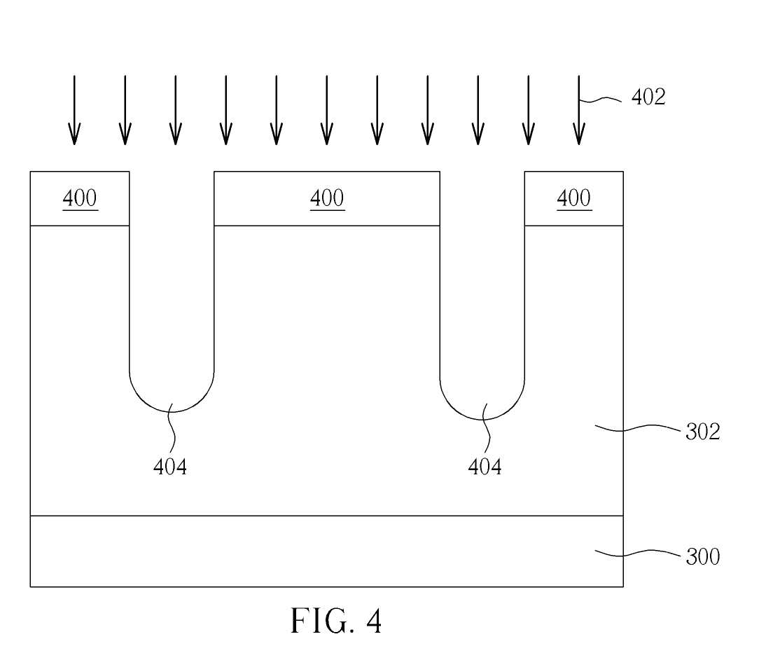

In FIG. 4, the semiconductor manufacturing process 20 forms a hard-mask layer 400 by photo resistor with photo exposure and develop process, and performs the dry etching process, e.g. RIE (Reactive Ion Etch) process 402, to generate the first trench 404.

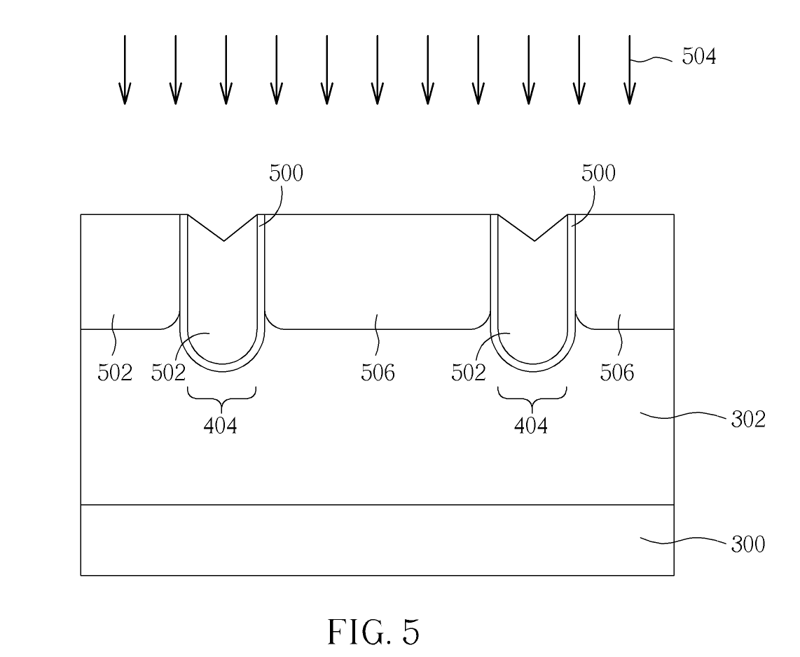

In FIG. 5, the semiconductor manufacturing process 20 forms a gate oxide layer 500 on the first trench 404 and deposits poly-Si 502 on the gate oxide layer 500 in the first trench 404. Then, the semiconductor manufacturing process 20 performs an boron implant process 504, which is preferably a thermal process for driving boron ions into the regions outside the first trench 404 and inside the epitaxy layer 302, so as to form a p-body region 506, and complete gate manufacturing.

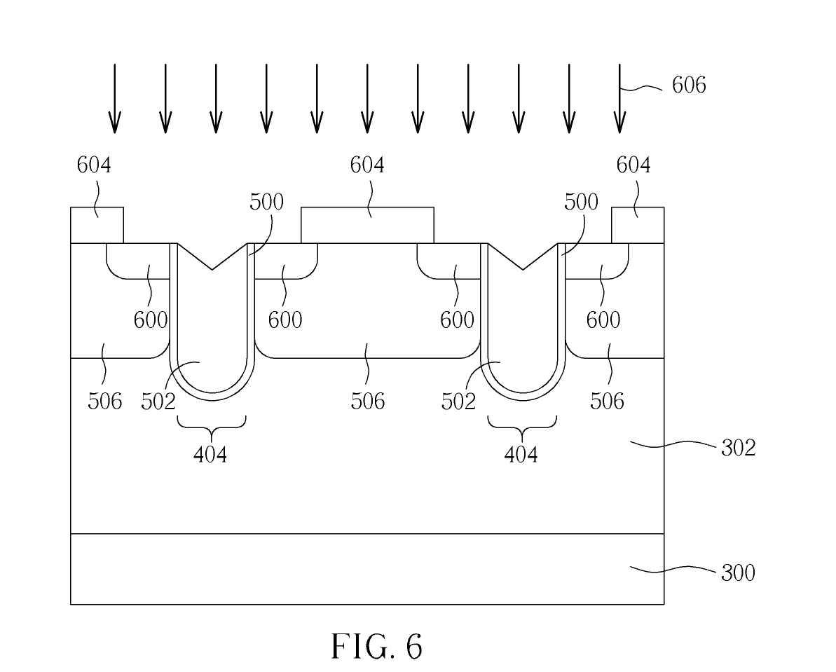

In FIG. 6, the semiconductor manufacturing process 20 uses photo resistor 604 defining regions of arsenic implant 606, and performs a thermal process to drive arsenic ions into the p-body region 506, to form a source region 600.

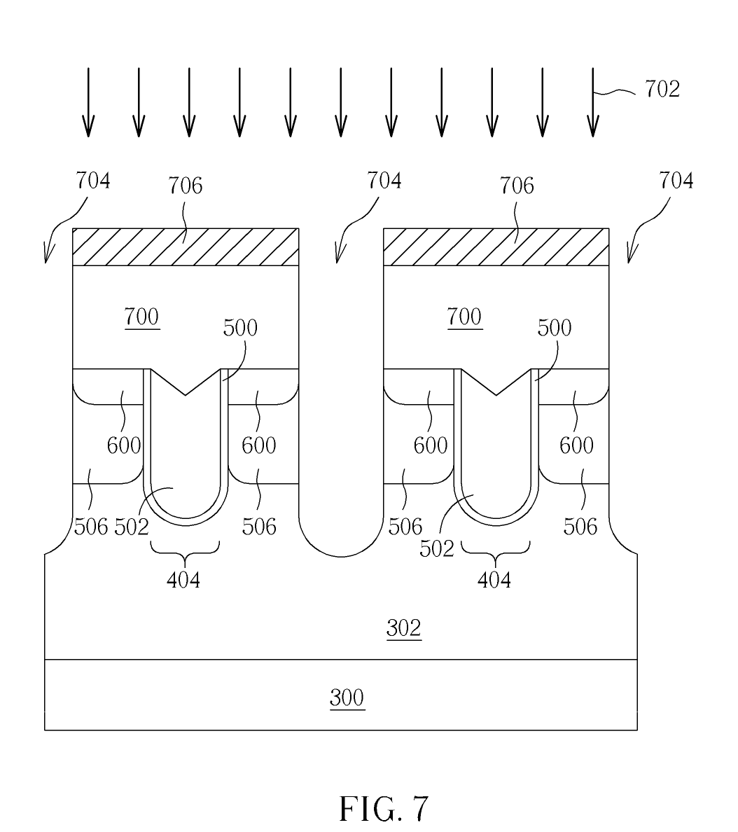

In FIG. 7, the semiconductor manufacturing process 20 deposits a first dielectric material 700 on the epitaxy layer 302, and preferably forms an HM (hard mask) oxide layer 706 on the epitaxy layer 302 first, and performs dry etching on the epitaxy layer 302 via a RIE process 702, to form a second trench 704.

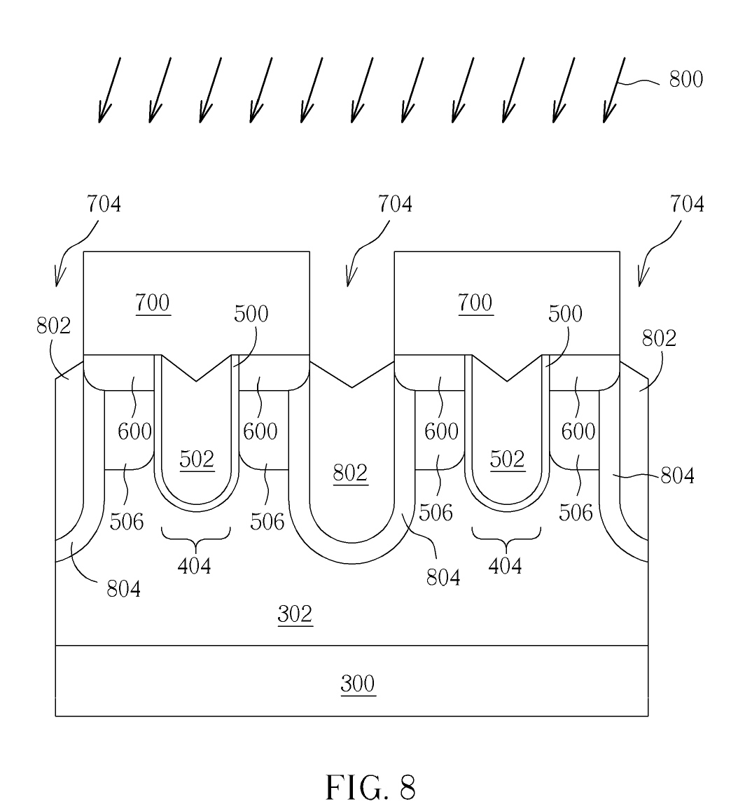

In FIG. 8, the semiconductor manufacturing process 20 preferably deposits conductive material 802 in the second trench 704 via a self-align implant process 800, and forms a p-well junction 804 on sidewalls of the second trench 704.

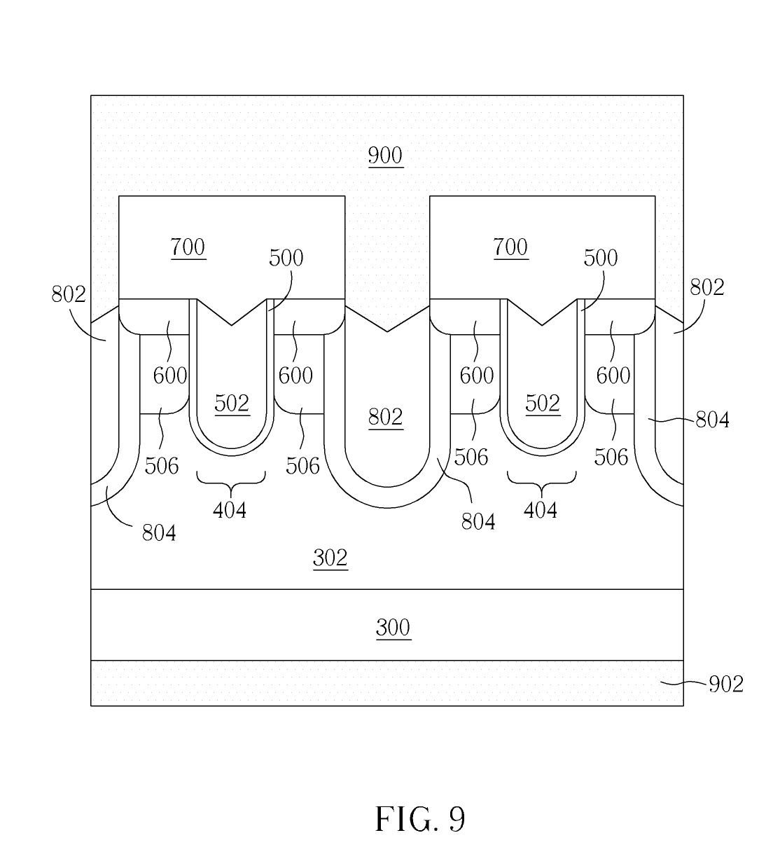

Finally, in FIG. 9, the semiconductor manufacturing process 20 performs a wet immersion process to form a etching contact hole, and deposits a frontside metal 900 (e.g. Al) and a backside metal 902 (e.g. Ti, Ni, or Ag), to complete the trench power transistor.

In summary, the present invention discloses the semiconductor manufacturing process for manufacturing the trench power transistor, so as to improve the prior art.

Those skilled in the art will readily observe that numerous modifications and alterations of the device and method may be made while retaining the teachings of the invention. Accordingly, the above disclosure should be construed as limited only by the metes and bounds of the appended claims.

1. A method for manufacturing a trench power transistor comprising:
providing a substrate;
forming an epitaxy layer on the substrate;
performing a dry etching process on the epitaxy layer for generating a first trench;
forming a gate oxide layer in the first trench and depositing poly-Si on the gate oxide layer in the first trench;
performing a boron implant process on regions outside the first trench and inside the epitaxy layer;
performing an arsenic implant process on regions beside the first trench and inside the epitaxy layer;
depositing a first dielectric material on the surface of the epitaxy layer;
performing a dry etching process on the epitaxy layer for generating a second trench;
depositing a conductive material in the second trench for forming a p-well junction on sidewalls of the second trench; and
performing a wet immersion process for forming a contact hole, and depositing a frontside metal and a backside metal.

2. The method of claim 1, wherein performing the dry etching process on the epitaxy layer for generating the first trench is performing a Reactive Ion Etch process on the epitaxy layer for generating the first trench.

3. The method of claim 1, wherein performing the dry etching process on the epitaxy layer for generating the first trench is performing the dry etching process on the epitaxy layer for generating the first trench by a mask defining a position of the first trench.

4. The method of claim 1, wherein performing the boron implant process on the regions outside the first trench and inside the epitaxy layer comprises:
depositing boron ions into the epitaxy layer; and
performing a thermal process for driving the boron ions into the regions outside the first trench and inside the epitaxy layer, so as to form a p-body region.

5. The method of claim 1, wherein performing the arsenic implant process on the regions beside the first trench and inside the epitaxy layer comprises:
depositing arsenic ions into the epitaxy layer; and
performing a thermal process for driving the arsenic ions into the regions beside the first trench and inside the epitaxy layer, so as to form an n+ source region.

6. The method of claim 1, wherein performing the dry etching process on the epitaxy layer for generating the second trench is performing the dry etching process on the epitaxy layer for generating the second trench by a mask defining a position of the second trench.

7. The method of claim 1, wherein the material of the frontside metal is Al.

8. The method of claim 1, wherein the material of the backside metal is Ti, Ni, or Ag.
